(19) United States
(12) Patent Application Publication
(10) Pub. No.: US 2006/0034063 A1
(43) Pub. Date: Feb. 16, 2006

(54) High-frequency device

(76) Inventors: Kam Choon Kwong, Singapore (SG); Ee Lae Lu, Singapore (SG)

Correspondence Address: PHILIPS INTELLECTUAL PROPERTY & STANDARDS, P.O. BOX 3001, BRIARCLIFF MANOR, NY, 10510, US

(21) Appl. No.: 10/533,723

(22) PCT Filed: Oct. 20, 2003
(86) PCT No.: PCT/IB03/04647

§ 371 Date: May 3, 2005

(30) Foreign Application Priority Data
Nov. 8, 2002 (WO) PCT/SG02/00301

(51) Int. Cl. H05K 5/04

(52) U.S. Cl. 361/829; 361/752

(57) ABSTRACT

A high-frequency device comprises a frame (2) provided with walls (12; 9-11) and leg sections (13; 16) extending from said walls. Said device further comprises a printed circuit board (3) extending perpendicularly to said walls, wherein said leg sections extend through holes (14; 19) in said printed circuit board and are connected to the printed circuit board by means of solder. At least one outer side wall of said frame is provided with at least one leg section which extends through a hole located in a part of said printed circuit board, which part extends through said outer side wall.

The invention relates to a device, particularly a high-frequency device, comprising a frame provided with walls and leg sections extending from said walls, said device further comprising a printed circuit board extending perpendicularly to said walls, wherein said leg sections extend through holes in said printed circuit board and are connected to the printed circuit board by means of solder.

In an embodiment of such a device, which is known from British patent application GB-A-2,318,690, a metal frame is provided with outer side walls as well as inner walls extending between the outer side walls. The inner walls of the metal frame are provided with leg sections extending through holes in the printed circuit board and are connected thereto by means of solder. Due to the leg sections, the printed circuit board is grounded. If such a device is used as an analog or a digital receiver, it is important that the printed circuit board is surrounded by said frame as much as possible. Furthermore, it is important to ground the printed circuit board also on the side edges.

In the known device it is not possible to ground the printed circuit board on the side edges other than by connecting the side edges directly to the outer side walls. This has the disadvantage that, due to thermal expansion coefficient differences between the printed circuit board and the metal frame, the connection between the printed circuit board and the fine will crack.

It is an object of the invention to provide a device, particularly a high-frequency device, wherein also an outer side wall is grounded in a reliable and easy manner.

This object is achieved by the device according to the invention in that at least one outer side wall of said frame is provided with at least one leg section which extends through a hole located in a part of said printed circuit board, which part extends through said outer side wall.

In this way, the whole printed circuit board, except for said part provided with said hole, can be surrounded by the frame, whilst simultaneously the printed circuit board is grounded by means of said part and the leg section of said outer side wall of said frame, which is located in the hole in said part.

Because the part of said printed circuit board extends through said outer side wall, the outer dimensions of the frame can remain the same as in prior-art devices. This has the advantage that the device can comply with international standards on the dimensions of such devices like receivers.

An embodiment of the device according to the invention is characterized in that said outer side wall is provided with at least one cut-out part, in which said leg section is located and through which the part of the printed circuit board extends.

Such an outer side wall can easily be made by punching, wherein a piece of said outer side wall is cut out to form the cut-out part whilst simultaneously forming the leg section.

Another embodiment of the device according to the invention is characterized in that all outer side walls are provided with leg sections extending through holes located in parts of the printed circuit board, which extend through said outer side walls.

In this way, optimal grounding of the device can be achieved.

The invention will be explained by way of example in more detail hereinafter with reference to the drawings in which:

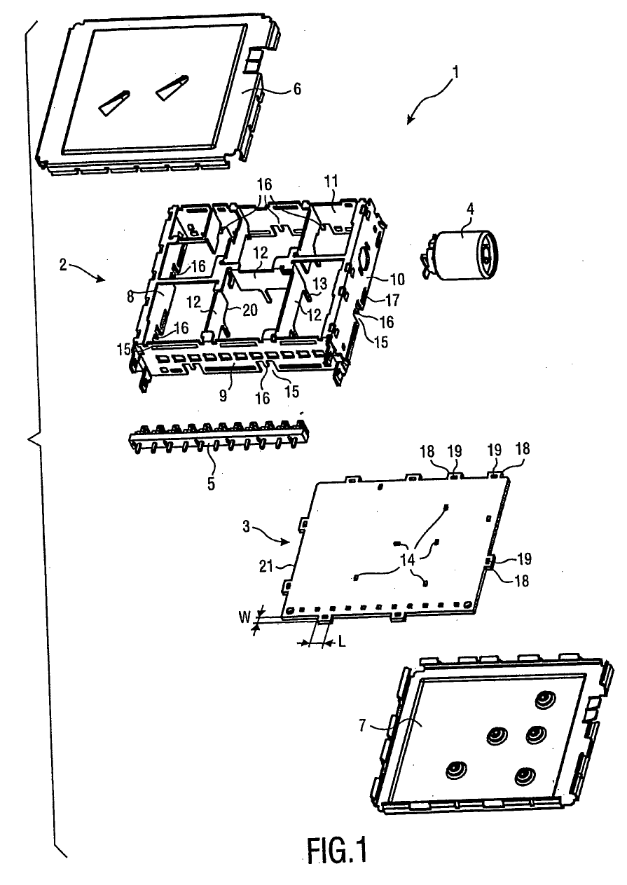

FIG. 1 is an exploded view of a device according to the invention,

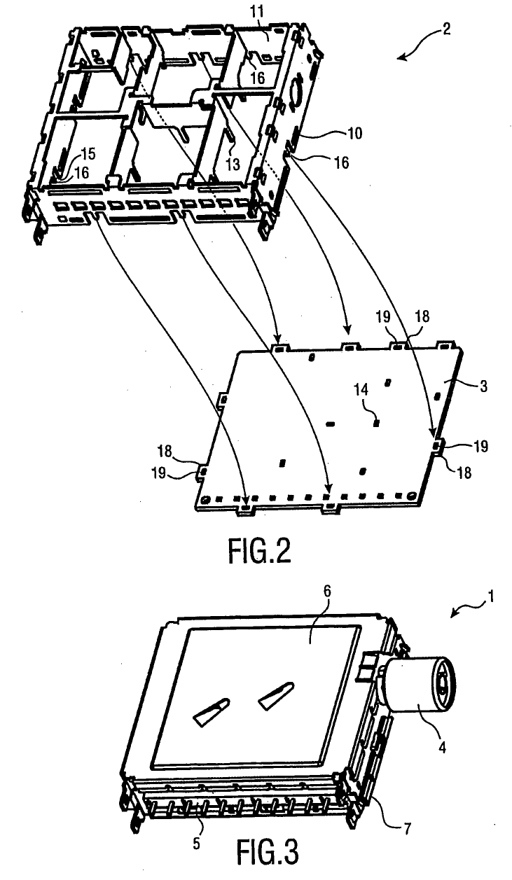

FIG. 2 is an exploded view of a frame and a printed circuit board of the device as shown in FIG. 1,

FIG. 3 is a perspective view of the device shown in FIG. 1,

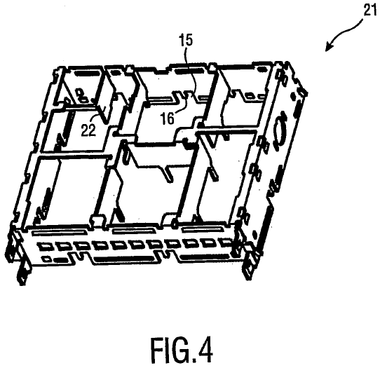

FIG. 4 is an exploded view of another Same of a device according to the invention.

Like parts are indicated by the same numerals.

FIG. 1 is an exploded view of a high-frequency (of) device 1 according to the invention, comprising a metal frame 2, a printed circuit board 3, a connector 4, a pin block 5 connected to said printed circuit board 3 and extending through said frame 2, and two covers 6, 7 extending parallel to said printed circuit board 3 and closing the metal frame 2 from below and above, as seen in FIG. 1.

The metal frame 2 is provided with four outer side walls 8, 9, 10, 11 between which inner walls 12 extend. The inner walls 12 comprise leg sections 13 which cooperate with holes 14 in the printed circuit board 3. The outer side walls 8-11 are provided with cut-out parts 15 from which U-shaped parts are cut out. In this way, leg sections 16 are formed on the outer side walls 8-11. The leg sections 13 extending from the inner walls 12 as well as the leg sections 16 in the outer side walls 8-11 are located on the same level with respect to the edges 17 of the outer side walls 8-11. The printed circuit board 3 is provided with parts 18 extending from the printed circuit board 3 in a direction parallel to the printed circuit board 3. In said parts 18, holes 19 are located which are aligned with the leg sections 16 of said frame 2.

When assembling the device 1, the frame 2 is connected to the printed circuit board 3 while the leg sections 13, 16 are inserted through the holes 14, 19, respectively. Edges 20 of the inner walls 12 then rest on the printed circuit board 3, while the outer side walls 8-11 surround the printed circuit board 3 and extend along edges 21 of the printed circuit board 3. The parts 18 are located in the cut-out parts 15, wherein the parts 18 have a width W which is nearly as large as the width of the cut-out parts 15. The length L of the parts 18 is preferably as small as possible but such that the parts 18 extend through the outer side walls 8-11 and that holes 19 can be provided therein for insertion of the leg sections 16. After the leg sections 13, 16 are inserted through the holes 14, 19, respectively, the leg sections 13, 19 are connected to the printed circuit board 3 by means of soldering to provide grounding means for the printed circuit board 3.

By means of the leg sections 13 extending from the inner walls 12 and the leg sections 16 located in the outer side walls 8-11, an easy and reliable method is provided for connecting as well as grounding the printed circuit board 3 to the frame 2.

FIG. 4 shows a frame 2′ which is similar to the frame 2, except that it comprises an additional inner wall 22, which shields unwanted oscillations to the IF output.

1. A device comprising a frame provided with walls and leg sections extending from said walls, said device further comprising a printed circuit board extending perpendicularly to said walls, wherein said leg sections extend through holes in said printed circuit board and are connected to the printed circuit board by means of solder, wherein at least one outer side wall of said frame is provided with at least one leg section which extends through a hole located in a part of said printed circuit board, which part extends through said outer side wall.

2. A high-frequency device as claimed in claim 1, wherein said outer side wall is provided with at least one cut-out part, in which said leg section is located and through which the part of the printed circuit board extends.

3. A high-frequency device as claimed in claim 1, wherein all outer side walls are provided with leg sections extending through holes located in parts of the printed circuit board, which extend through said outer side walls.
